(19) United States
(12) Patent Application Publication
(10) Pub. No.: US 2015/0103496 A1
(43) Pub. Date: Apr. 16, 2015

(54) POWER CONVERSION AND CONNECTION FOR PHOTOVOLTAIC (PV) PANEL ARRAYS

(71) Applicant: Quietside, Inc., Fort Worth, TX (US)

(72) Inventors: Dale R. Anderson, Colleyville, TX (US); Derek Frank, North Richland Hills, TX (US)

(21) Appl. No.: 14/051,875

(22) Filed: Oct. 11, 2013

(51) Int. Cl. H05K 7/00; H05K 13/04

(52) U.S. Cl. CPC H05K 7/00; H05K 13/0469
USPC 361/729; 29/592.1

(57) ABSTRACT

A solar energy collection and power generation element is described. The solar energy and collection element includes: a photovoltaic (PV) panel having a set of DC outputs; and a power management module coupled to the PV panel. The power management module includes: a base module having a connector adapted to receive electrical energy produced by the PV panel from the set of DC outputs; and a removable inverter that is able to be coupled to the base module via the connector, the removable inverter adapted to receive a DC voltage from the connector, generate an AC voltage, and provide the generated AC voltage to the connector. A solar energy collection system includes: a support structure and multiple PV panels mounted to the support structure. A method of manufacturing an integrated solar panel product includes: retrieving a panel body; retrieving a power module; and attaching the power module to the body.

### BACKGROUND OF THE INVENTION

Due to rising energy costs, sustainability concerns, and other reasons, use of photovoltaic (PV) panels to convert solar radiation to electrical power is common. Such panels may typically be grouped in an array to provide power to a load or grid.

In a typical installation, direct current (DC) power produced by each panel may be provided through a DC junction box that is then connected to an external inverter. Each panel may be connected to a separate external inverter or a set of panel outputs may be combined before being connected to an external inverter. Such connection schemes include exposed high voltage DC that requires ground fault protection, where a separate ground fault protector may be required for each inverter.

Such schemes may require separate installation of each panel and an associated inverter. In addition, use of alternating current (AC) trunk cables may require separate installation operations. Inverters may also require a frame or other support or mounting hardware that is separate from the hardware used to mount a PV panel.

In some connection schemes, a micro inverter may be attached to a frame of the PV panel. Such an approach requires cabling to connect a DC junction box of the panel to the inverter and cabling to connect the inverter output to an AC connection. In addition, test or repair of the panels may be difficult as the inverter may not be easily removed from the panel frame and also requires that various external cables be disconnected and reconnected.

Therefore, there exists a need for a power conversion and connection scheme that eliminates exposed high voltage DC, allows for use of frameless PV panels, allows for test and/or repair of individual panels from an array, and eliminates the need for external inverters or AC cables.

### BRIEF SUMMARY OF THE INVENTION

Some embodiments of the invention provide a PV panel that includes an attached power module. Such a power module may include a base component that is coupled to a surface of the PV panel. The power module may also include a removable inverter that is able to be coupled to the base component. Alternatively, a removable measurement module may be coupled to the base component. The power module may include a set of AC connection cables that allow the output from the panel to be connected to outputs from other panels (and/or to an external power grid).

A first exemplary embodiment of the invention provides a solar energy collection and power generation element. The solar energy and collection element includes: a PV panel having a set of DC outputs; and a power management module coupled to the PV panel. The power management module includes: a base module having a connector adapted to receive electrical energy produced by the PV panel from the set of DC outputs; and a removable inverter that is able to be coupled to the base module via the connector, the removable inverter adapted to receive a DC voltage from the connector, generate an AC voltage, and provide the generated AC voltage to the connector.

A second exemplary embodiment of the invention provides a solar energy collection system. The system includes: a support structure; at least one of a point of presence load and a utility grid associated with the support structure; and multiple photovoltaic (PV) panels mounted to the support structure and connected to at least one of the point of presence load and the utility grid. Each particular PV panel includes: a power management base module having a connector adapted to receive electrical energy produced by the particular PV panel from a set of associated DC outputs; and a removable inverter that is able to be coupled to the power management base module via the connector, the removable inverter adapted to receive a DC voltage from the connector, generate an AC voltage, and provide the generated AC voltage to the connector.

A third exemplary embodiment of the invention provides a method of manufacturing an integrated solar panel product. The method includes: retrieving a panel body; retrieving a power module; and attaching the power module to a rear surface of the body.

The preceding Summary is intended to serve as a brief introduction to various features of some exemplary embodiments of the invention. Other embodiments may be implemented in other specific forms without departing from the spirit of the invention.

### BRIEF DESCRIPTION OF THE SEVERAL VIEWS OF THE DRAWINGS

The novel features of the invention are set forth in the appended claims. However, for purpose of explanation, several embodiments of the invention are set forth in the following drawings.

FIG. 1 illustrates a rear view of an integrated photovoltaic (PV) panel and power management features of some embodiments;

FIG. 2 illustrates a front view of the interior of a module base included with some embodiments of the integrated PV panel of FIG. 1;

FIG. 3 illustrates a rear view of the interior of a removable inverter adapted by some embodiments to be coupled to the module base of FIG. 2;

FIG. 4 illustrates a rear view of the interior of a removable measurement module adapted by some embodiments to be coupled to the module base of FIG. 2;

FIG. 5 illustrates a side view of the integrated PV panel of FIG. 1;

FIG. 6 illustrates an exploded side view of the integrated PV panel of FIG. 1;

FIG. 7 illustrates a rear view of a portrait layout of PV panels implemented using the PV panel of FIG. 1;

FIG. 8 illustrates a rear view of a landscape layout of PV panels implemented using the PV panel of FIG. 1;

FIGS. 9A-9D illustrate rear views of various alternative layouts of PV panels implemented using the PV panel of FIG. 1;

FIG. 10 illustrates a flow chart of a process used by some embodiments to manufacture the PV panel of FIG. 1; and

FIG. 11 illustrates a flow chart of a process used by some embodiments to measure performance of the PV panel of FIG. 1.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, as the scope of the invention is best defined by the appended claims.

Various inventive features are described below that can each be used independently of one another or in combination with other features. Broadly, embodiments of the present invention generally provide a power module that is able to be attached to a surface of a PV panel. The module may include a base which is electrically coupled to a DC output of the PV panel. The module may further include a removable inverter that may be coupled to the base in order to generate an AC output from the DC panel output. Alternatively, a measurement module may be coupled to the base to evaluate the performance of the panel.

Several more detailed embodiments of the invention are described in the sections below. Section I provides a conceptual description of a system architecture of some embodiments. Section II then describes various arrangement schemes for panel arrays allowed by some embodiments. Lastly, Section III describes methods of manufacturing and evaluating a PV panel of some embodiments.

### I. System Architecture

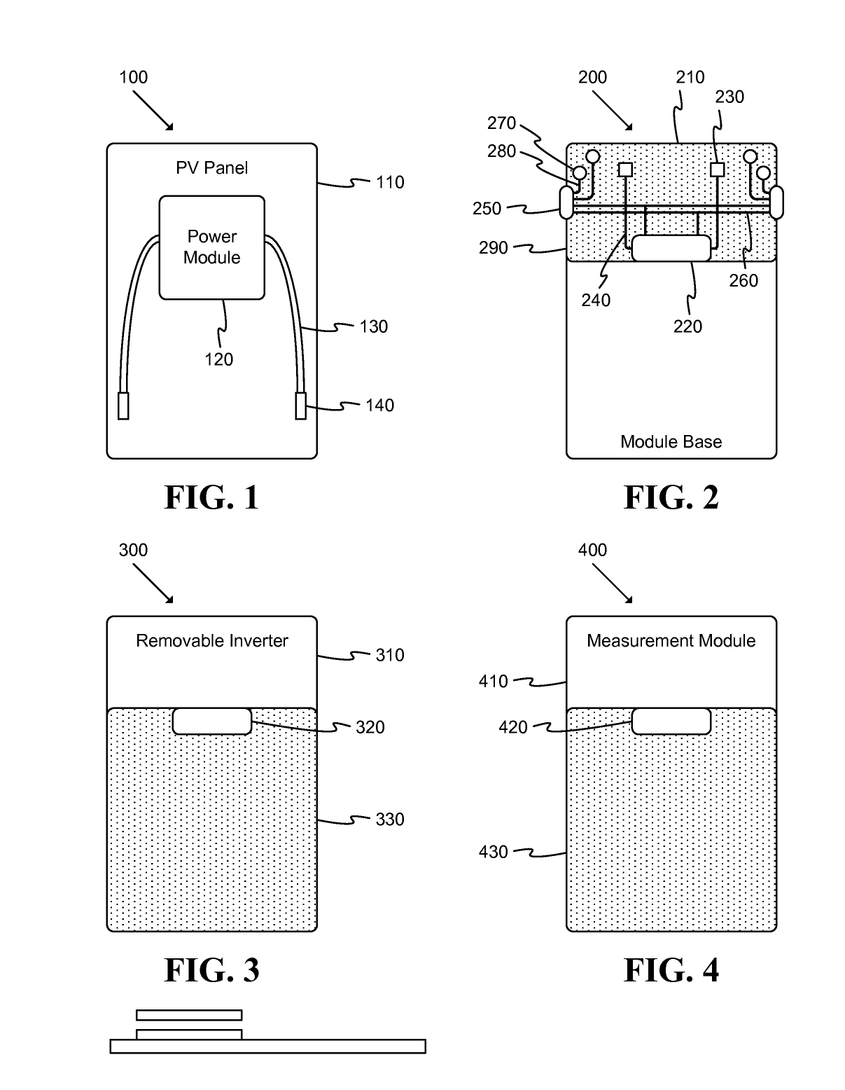

FIG. 1 illustrates a rear view (i.e., a view of the opposite surface to the surface of the panel intended to absorb solar radiation) of an integrated photovoltaic (PV) panel 100 and power management features of some embodiments. Specifically, this figure shows various external components of the integrated PV panel. As shown, the integrated panel may include a panel body 110, a power module 120, and a set of AC cables 130, which each may include a connector 140.

The panel body 110 may include the PV panel itself and may have a frame or be frameless. The panel body may include one or more DC outputs (not shown).

The power module 120 may include various appropriate components that may allow the DC outputs of the panel to be converted to AC power. The power module will be described in more detail in reference to FIGS. 2-3 below.

Each AC cable 130 may include appropriately-sized internal wiring and an external covering adapted to protect and shield the wiring. The AC cable may include multiple internal wires (e.g., two, four, etc.). Each cable may have a length sufficient to allow various panel arrangements (as described in more detail in Section II below).

Each connector 140 may be adapted to be coupled to a connector included in a different panel, or to an external grid or point of presence load (e.g., a home, business, etc.). In some embodiments, the connectors may be twenty amp locking connectors. Different embodiments my use different specific connectors.

FIG. 2 illustrates a front view of the interior of a module base 200 of the power module 120. Specifically, this figure illustrates various internal components of the module base 200. As shown, the module base may include a body or case 210, a connector 220, a set of DC panel connections 230 and associated connector connections 240, a set of cable terminals or ports 250 and associated cable connections 260, a set of module connection terminals 270 and associated connections 280, and a component area 290 that spans a portion of the module base 200.

The body or case 210 may be generally rectangular, as shown. The body may be made of various appropriate materials (e.g., metal, plastic, etc.) or combinations of materials.

The connector 220 may be any appropriate connector that allows the base 200 to be coupled to other power module components such as a removable similar to that described below in reference to FIG. 3 or a measurement module similar to that described below in reference to FIG. 4.

The set of DC panel connections 230 may be electrically coupled to DC outputs of a PV panel. Such electrical coupling may include combinations of wires, printed circuit board (PCB) connections, solder connections, etc. The DC panel connections may be coupled to the connector 220 via the connector connections 240, which may include various combinations of wires, PCB connection, solder connections, etc.

Each cable port 250 may include a through-hole, clamp, sealant, and/or other appropriate elements that allow a cable to be connected to the base 200. The cable connections 260 may electrically couple wires of the cable to the connector 220. In some embodiments, the connections 260 may include a “T” junction for connecting AC wires from each cable to the appropriate AC connection of the connector 220. The connections 260 may include various connection features that may allow the cable wires to be electrically connected to the connections. Such connection features may include, for instance, solder terminals, crimp terminals, screw terminals, PCB connections, etc.

Each module connection terminal 270 may provide an electrical connection to elements of the module base 200 (e.g., a ground connection, a panel connection, etc.). The associated connections 280 may include, for instance, portions of the cable wires themselves, solder terminals, crimp terminals, PCB connections, etc.

The component area 290 may include a PCB (and/or other appropriate elements) that supports the various electrical components included in the module base 200. In Some embodiments, the portion of the base 200 that does not include the component area 290 may be left empty such that an associated element such as a removable inverter may utilize the space for components included in the associated element.

FIG. 3 illustrates a rear view of the interior of a removable inverter 300 adapted to be coupled to the module base 200. Specifically, this figure illustrates various internal components of the inverter 300. As shown, the removable inverter may include a body or case 310, a connector 320, and a component area 330.

The body 310 may be generally rectangular, as shown. The body may be made of various appropriate materials (e.g., metal, plastic, etc.) or combinations of materials. The body may be adapted to be attached to the base body 210. For instance, the body 310 may have walls that are sized to extend into a cavity formed by the base body 210 such that the two body elements 210 and 310 may be physically coupled to each other. In some embodiments, the one or more of the body elements 210 and 310 may include a gasket or other appropriate seal such that the assembled module 120 is able to operate under a range of environmental conditions, such as those encountered when a panel is mounted to an exterior surface of a structure.

The connector 320 may be adapted to allow the inverter 310 to be electrically connected to the base 210 via the base connector 220. The connectors 220 and 320 may be sized and/or otherwise adapted to be able to reliably transfer the DC voltage produced by the panel from the base 200 to the inverter 300 and receive the AC voltage generated, in turn, buy the inverter and returned to the base 200.

The component area 330 may include a PCB (and/or other appropriate elements) that supports and/or connects the various electrical components included in the inverter 300, at least some of which may be accessible (directly and/or indirectly) via the connector 320. The inverter 300 may include various types of appropriate circuitry such as wires or connectors, switches, transistors, diodes, capacitors, etc. (not shown). The component area 330 may allow the inverter components to fit within the portion of the base 200 that does not include component area 290 such that the base components and inverter components fit within the assembled power module 120.

FIG. 4 illustrates a rear view of the interior of a removable measurement module 400 adapted to be coupled to the module base 200. Specifically, this figure illustrates the internal components of the measurement module 400. As shown, the measurement module may include a body or case 410, a connector 420, and a component area 430.

The body 410 and connector 420 may be generally similar to the body 310 and connector 320 described above.

The component area 430 may allow the inverter components to fit within the portion of the base 200 that does not include component area 290 such that the base components and inverter components fit within the assembled power module 120.

The component area 430 may include a PCB (and/or other appropriate elements) that supports and/or connects the various electrical components included in the measurement module 400. The measurement module may include circuitry adapted to measure and/or log various performance data associated with the operation of the integrated panel. Such performance data may include, for instance, DC output voltage and/or current, AC line telemetry, and/or other appropriate parameters. In some embodiments, the measurement module may be able to store measured data and/or transfer such data to an external device or system (e.g., by connecting the measurement module to a smartphone, tablet device, or personal computer via a wired or wireless connection).

The measurement module of some embodiments may include components that allow the module to measure performance directly and provide feedback through one or more user interface elements (not shown). For instance, the measurement module may display DC voltage levels using an alphanumeric display. As another example, the measurement module may include various indicator elements (e.g., a green light, a yellow light, a red light, etc.) that may correspond to various operating conditions (e.g., operating within specified range, operating outside specified range, non-operational, etc.).

The measurement module may include various user interface elements (e.g., buttons, keypad or keyboard, touchscreen, etc.) that may allow a user to at least partially control operation of the module. For instance, a user may be able to select various test modes, display modes, etc. As another example, a user may be able to select from sets of evaluation criteria that may be associated with, for instance, different types or sizes of panels, different types of operating conditions, and/or other appropriate variations.

By allowing the inverter 300 to be easily removed from the base 200, the measurement module 400 may be attached to the base 200 without disturbing the DC panel connections or the intra-panel AC connections. In this way, the performance of a panel may be easily evaluated with minimal downtime for the system.

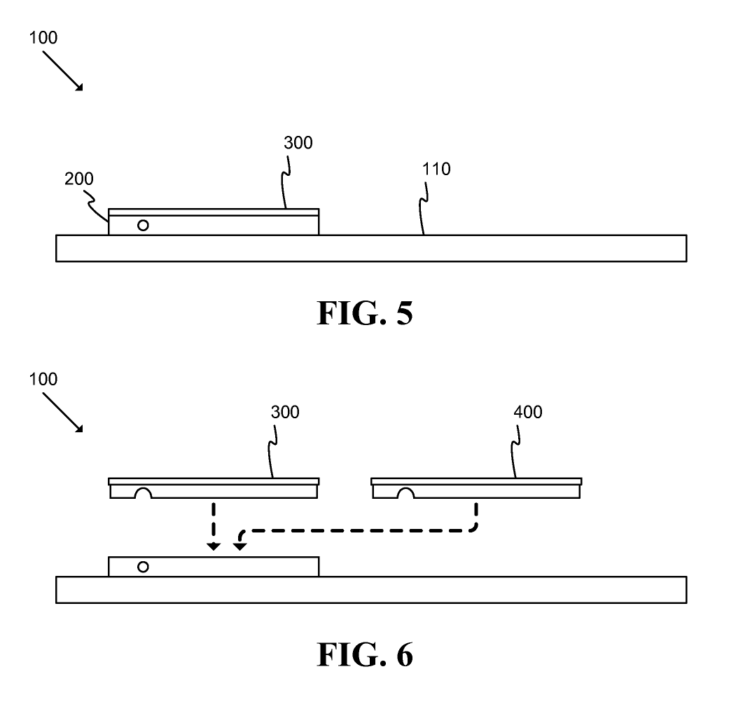

FIG. 5 illustrates a side view of the integrated PV panel 100. The AC cables are omitted for clarity. As shown, the module base 200 may be coupled to the panel body 110, and the removable inverter 300 may be coupled to the base 200.

FIG. 6 illustrates an exploded side view of the integrated PV panel 100. The AC cables are omitted for clarity. As shown, the module base 200 may be alternatively coupled to the inverter 300 and the measurement module 400. Either the inverter 300 or measurement module 400 may be attached to the base 200 in various appropriate ways. In the example of FIG. 6, the bodies of the inverter 300 and measurement module 400 are sized and otherwise configured such that a portion of each body fits within the body of the base 200 to form a compression fit. In addition, the socket included in the base 200, and the associated socket in the inverter 300 or measurement module 400 may be adapted to “lock” in place such that, when connected, the associated sockets cause the removable elements 300 and 400 to be held in position relative to the base 200.

One of ordinary skill in the art will recognize that the various elements described above in reference to FIGS. 1-6 are conceptual in nature and different embodiments may be implemented in different specific ways without departing from the spirit of the invention. For instance, different embodiments may include elements of different absolute or relative size, of different shape, etc. than those shown. In addition, various elements may be omitted in some embodiments or various other elements may be included. Furthermore, the various elements may be arranged in various different ways.

### II. Arrangement Schemes

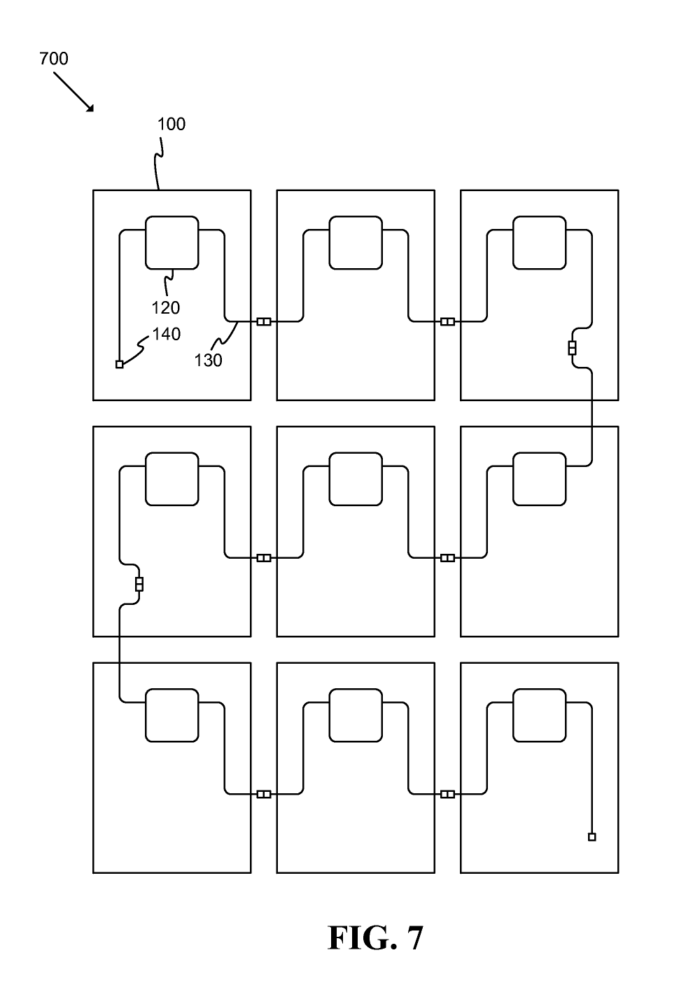

Various users may wish to install sets of panels in various configurations, depending on factors such as budget, access to sunlight, characteristics of the support structure (e.g., size, dimensions, features, etc.), and/or other relevant factors. FIGS. 7-9 illustrate several example arrangements that are allowed by the integrated panel of some embodiments.

FIG. 7 illustrates a rear view of a portrait layout 700 of integrated PV panels 100. Such an arrangement may be desirable, for instance, when placing an array of PV panels on a surface having a rectangular shape with a long height relative to width.

In each of the arrangements of FIGS. 7-9, the panels 100 may be attached to a structure in various appropriate ways (e.g., using a metal frame, using various connection elements such as nuts, bolts, etc., using various types of adhesive elements, etc.). As above, in the view of FIGS. 7-9, the rear of the panel body is visible (i.e., the opposite surface to the surface of the panel intended to absorb solar radiation). As shown, each panel 100 may include a power module 120, AC cables 130, and connectors 140. The panels may be connected in a “daisy-chain” fashion, such that each panel is connected to at least one other panel. In such a configuration, the first and last panel in the array may each have a cable that is connected to an external element (e.g., a load, an electric grid, etc.). The cables 130 may have an appropriate length such that the panels 100 may be connected to each other (and/or to an external element) as shown in each arrangement.

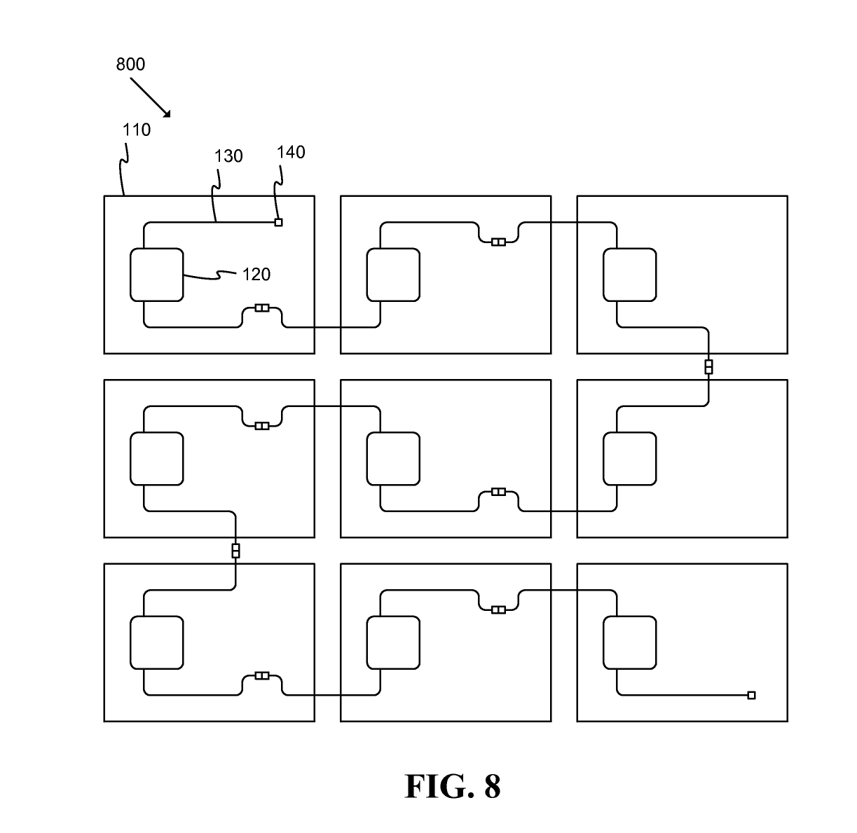

FIG. 8 illustrates a rear view of a landscape layout 800 of PV panels 100. Such an arrangement may be desirable, for instance, when placing an array of PV panels on a surface having a rectangular shape with a long width relative to height.

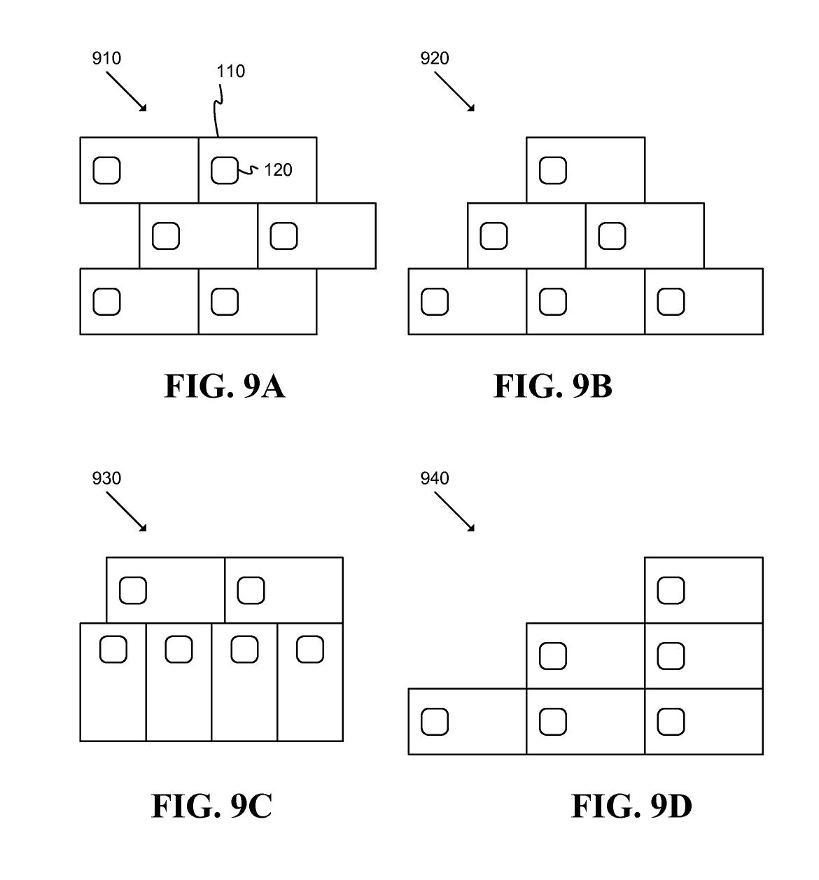

FIGS. 9A-9D illustrate rear views of various alternative layouts 910-940 of PV panels 100. Such arrangements 910-940 may be desirable, for instance, when placing an array of panels on a surface having an irregular shape, a surface with existing features (e.g., windows, doors, skylights, etc.), and/or other appropriate surfaces. In addition, some arrangements may be utilized for aesthetic reasons.

FIG. 9A illustrates a staggered module layout 910 allowed by some embodiments. FIG. 9B illustrates a hybrid orientation layout 920 allowed by some embodiments. FIG. 9C illustrates a pyramid layout 930 allowed by some embodiments. FIG. 9D illustrates a stair-step layout 940 allowed by some embodiments.

One of ordinary skill in the art will recognize that the arrangement schemes of FIGS. 7-9 are for example purposes only and that various different arrangements may be allowed. In addition, although the panels are shown as having a rectangular shape, different embodiments may include panels of different shape (e.g., square, round, oval, various polygons, etc.), size, dimension, etc.

### III. Manufacture and Evaluation

The processes described below may be used by some embodiments to manufacture and/or evaluate products that are adapted to provide various elements described above in relation to FIGS. 1-9. These processes are presented for example purposes only, and different embodiments may be manufactured and/or evaluated in various different ways than those presented below.

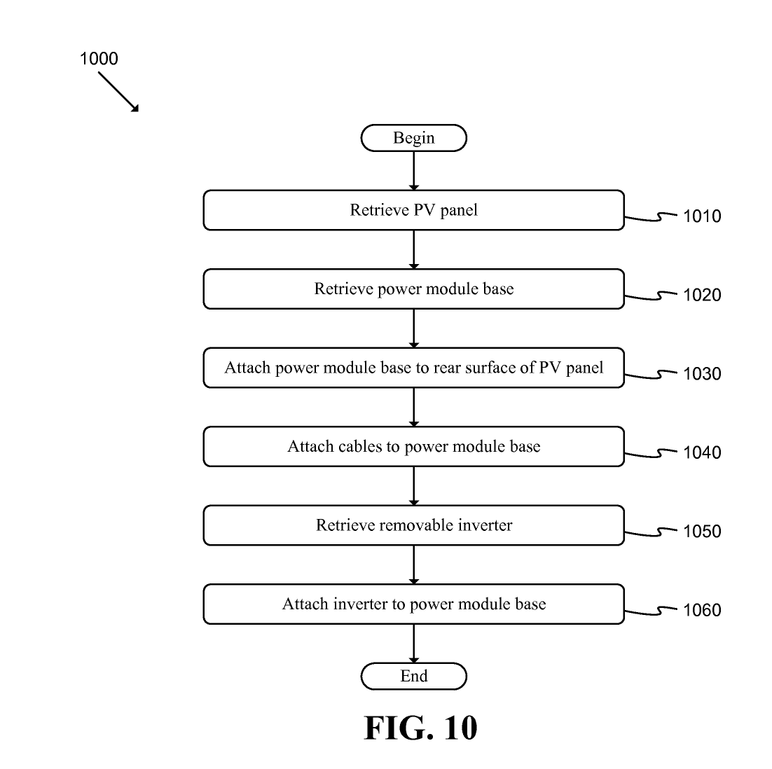

FIG. 10 illustrates a flow chart of a process 1000 used by some embodiments to manufacture a PV panel such as integrated PV panel 100 described above. Such a process may begin, for instance, when individual panel elements are available.

As shown, the process may first retrieve (at 1010) a PV panel (e.g., the PV panel 110). Next, the process may retrieve (at 1020) a power module base such as base 200 described above.

Process 1000 may then attach (at 1030) the power module base to a rear surface of the PV panel (i.e., the surface opposite the surface adapted to collect solar radiation). The base may be attached to the panel in various appropriate ways. For instance, some embodiments may use silicone sealant, very high bond (VHB) acrylic foam tape, and/or other appropriate elements. Alternatively, the base may be attached to the panel using a frame or support that is also attached to the panel.

Next, the process may attach (at 1040) cables to the base. For instance, cables 130, as described above, may be attached to base 200. Alternatively, the cables may be attached to the base before the base is attached to the panel. The cables may be attached to the base in various appropriate ways (e.g., using clamps, connectors, terminals, adhesives, sealants, etc.).

The process may then retrieve (at 1050) a removable inverter (e.g., inverter 300) and attach (at 1060) the inverter to the base and then may end. The inverter may be attached to the base in various appropriate ways. For instance, the elements may form a compression fit. In addition, as described above, the base and inverter will have associated connection sockets that may lock in place when the inverter socket engages the base socket. Furthermore, the inverter may be connected to the base in various ways (e.g., using screws, rivets, adhesives, gaskets, seals, etc.), as appropriate.

The various elements used in process 1000 (e.g., the PV panel, the module base, the removable inverter, etc.) may be manufactured in various appropriate ways. In some embodiments, the operations of process 1000 may be automatically implemented using various appropriate manufacturing elements (e.g., handlers, computer-controlled machines, etc.).

One of ordinary skill in the art will recognize that process 1000 is conceptual in nature and may be implemented in various different specific ways without departing from the spirit of the invention. For instance, the operations of the process may be performed in different orders. As another example, additional operations may be included and/or various operations may be omitted. In addition, the process may be executed as part of a larger macro process or broken up into a set of sub-processes.

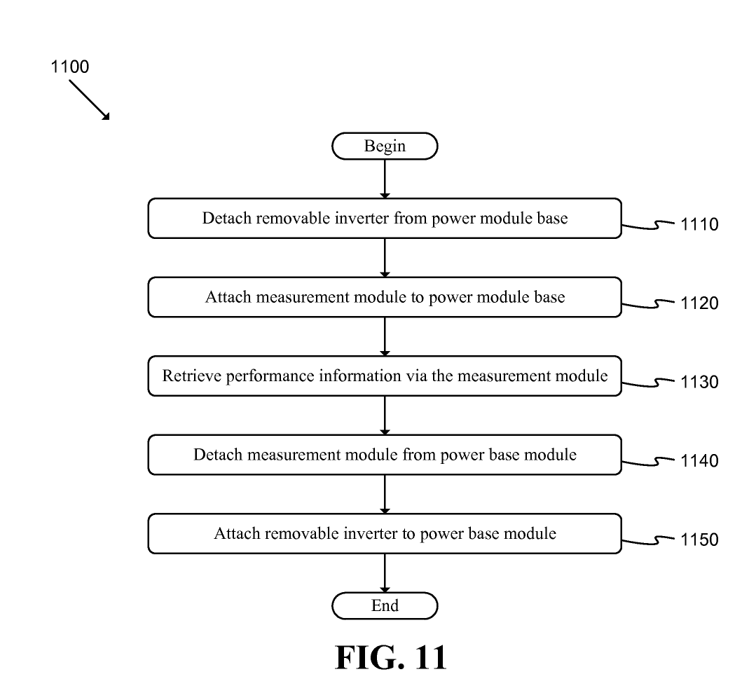

FIG. 11 illustrates a flow chart of a process used by some embodiments to measure performance of a PV panel such as integrated PV panel 100 described above. Such a process may begin, for instance, when a set of panels is installed, during regular maintenance, and/or at other appropriate times.

As shown, the process may detach (at 1110) a removable inverter (e.g., inverter 300) from a power module base (e.g., base 200). The inverter may be detached by pulling the inverter body away from the base.

Next, the process may attach (at 1120) a measurement module (e.g., module 400) to the power module base. The measurement module may be attached in various appropriate ways, similar to attachment of the inverter described above in reference to process 1000.

The process may then retrieve (at 1130) performance information via the measurement module. Such information may include, for instance, DC voltage information, resistance, etc. The measurement module may provide the information to an external element (e.g., a smartphone, a personal computer, etc.) through a wire or wireless connection. Alternatively, the measurement module may store the information for later use by an external element.

Next, the process may detach (at 1140) the measurement module from the power base module. The measurement module may be detached by pulling the inverter body away from the base.

Process 1100 may then attach (at 1150) the removable inverter to the power base module and then may end. The removable inverter may be attached in various appropriate ways, as described above in reference to process 1000.

One of ordinary skill in the art will recognize that process 1100 is conceptual in nature and may be implemented in various different specific ways without departing from the spirit of the invention. For instance, the operations of the process may be performed in different orders. As another example, additional operations may be included and/or various operations may be omitted. In addition, the process may be executed as part of a larger macro process or broken up into a set of sub-processes.

It should be understood, of course, that the foregoing relates to illustrative details of exemplary embodiments of the invention and that modifications may be made without departing from the spirit and scope of the invention as defined by the following claims.

We claim:

1. A solar energy collection and power generation element comprising:
a photovoltaic (PV) panel having a set of DC outputs; and
a power management module coupled to the PV panel, the power management module comprising:
a base module having a connector adapted to receive electrical energy produced by the PV panel from the set of DC outputs; and
a removable inverter that is able to be coupled to the base module via the connector, the removable inverter adapted to receive a DC voltage from the connector, generate an AC voltage, and provide the generated AC voltage to the connector.

2. The solar energy collection and power generation element of claim 1, wherein the base module is coupled to a surface of the PV panel using at least one of silicone sealant and very high bond acrylic foam tape.

3. The solar energy collection and power generation element of claim 1 further comprising a set of AC cables adapted to receive the generated AC voltage from the connector and provide the AC voltage to an external element.

4. The solar energy collection and power generation element of claim 3, wherein the external element is one of a point of presence load and a utility grid.

5. The solar energy collection and power generation element of claim 3, wherein the external element is another solar energy collection and power generation element.

6. The solar energy collection and power generation element of claim 3, wherein each AC cable in the set of AC cables includes a locking twenty amp connector adapted to be coupled to another locking twenty amp connector.

7. The solar energy collection and power generation element of claim 1, wherein the PV panel is a frameless panel.

8. A solar energy collection system comprising:
a support structure;
at least one of a point of presence load and a utility grid associated with the support structure; and
a plurality of photovoltaic (PV) panels mounted to the support structure and connected to at least one of the point of presence load and the utility grid, each particular PV panel comprising:
a power management base module having a connector adapted to receive electrical energy produced by the particular PV panel from a set of associated DC outputs; and
a removable inverter that is able to be coupled to the power management base module via the connector, the removable inverter adapted to receive a DC voltage from the connector, generate an AC voltage, and provide the generated AC voltage to the connector.

9. The solar energy collection system of claim 8, wherein the particular PV panel further comprises a set of AC cables adapted to receive the generated AC voltage from the connector and provide the AC voltage to the at least one of the point of presence load and the utility grid.

10. The solar energy collection system of claim 9, wherein the plurality of PV panels is able to be arranged in a portrait configuration.

11. The solar energy collection system of claim 9, wherein the plurality of PV panels is able to be arranged in a landscape configuration.

12. The solar energy collection system of claim 9, wherein the plurality of PV panels is able to be arranged in a staggered configuration.

13. The solar energy collection system of claim 9, wherein the plurality of PV panels is able to be arranged in a pyramid configuration.

14. The solar energy collection system of claim 9, wherein the plurality of PV panels is able to be arranged in a stair-step configuration.

15. A method of manufacturing an integrated solar panel product, the method comprising:
retrieving a panel body;
retrieving a power module; and
attaching the power module to a rear surface of the body.

16. The method of claim 15, wherein the power module is attached to the rear surface of the body using silicone sealant.

17. The method of claim 15, wherein the power module is attached to the rear surface of the body using very high bond acrylic foam tape.

18. The method of claim 15, wherein attaching the power module to the rear surface of the body comprises:
attaching a base element of the power module to the rear surface of the body; and
attaching a removable inverter element of the power module to the base element.

19. The method of claim 18, wherein the removable inverter element is electrically coupled to the base element when attached.

20. The method of claim 15 further comprising attaching a set of AC cables to the power module.
